(19) United States
(12) Patent Application Publication
(10) Pub. No.: US 2026/0052635 A1
(43) Pub. Date: Feb. 19, 2026

(54) CABLE VENT

(71) Applicant: Universal Air Filter Company, Sauget, IL (US)

(72) Inventors: Christopher Thomas Picha, Imperial, MO (US); John Thomas Pellerin, Nahant, MA (US)

(21) Appl. No.: 19/288,684

(22) Filed: Aug. 1, 2025

Related U.S. Application Data
(60) Provisional application No. 63/678,315, filed on Aug. 1, 2024.

(51) Int. Cl. H05K 5/02; H05K 7/18

(52) U.S. Cl. CPC H05K 5/0214; H05K 7/18

(57) ABSTRACT

An improved cable management system used in connection with electronic equipment and devices which allows for wires and cables to pass through the vent and prevent dust ingress. The improved cable management system is comprised of a foam baffle which is fully customizable to fit into nearly any type of electronic enclosure and is rated UL94 (V0 or HF-1) per UL flammability standards.

### CROSS-REFERENCE TO PRIOR APPLICATIONS

The present application claims priority to U.S. Provisional Application No. 63/678,315 filed on Aug. 1, 2024 which is incorporated herein.

### FIELD OF DISCLOSURE

The present invention generally relates to an improved cable management system used in connection with electronics equipment to prevent dust ingress.

### BACKGROUND

Current cable management systems for use with enclosures of electronic devices generally consist of brush-like devices which must be custom-built for specific devices and mounted using sheet metal or other hardware methods. Common examples of known cable management systems include grommet type, fixed brush, and bush strip configurations. These known cable management systems are applied to enclosures for telecommunications, networking, datacenter, medical, military, and industrial devices.

Known cable management systems are limited to fixed dimensions. While these systems can be cut to length, they remain solely linear solutions. Further, the traditional brush-like devices include bristles which make it challenging to configure the cable routing in the most efficient pathways.

There exists a need in the art for a cable management system which is configurable to any type of device, designed to achieve optimal cable routing paths, and capable of preventing dust ingress. Instead of altering an enclosure to fit a standard cable management device, there exists a need for configurable cable management device to fit desired electronic device enclosures.

### SUMMARY OF DISCLOSURE

The present invention is directed to an improved cable management system used on electronics equipment that allows wires and cables to pass through the vent and prevent dust ingress. The improved cable management system is conceived to be a customizable device that can be configured to fit to any electronic enclosure that needs to allow wires/cables to pass through an enclosure while limiting unfiltered air bypass. The improved cable management system can be designed to fit the enclosure, not altering the enclosure to fit typical cable brush limitations. The improved cable management system consists of a polypropylene frame and a polyurethane foam baffle rated to UL94 (V0 or HF-1) per UL flammability standards. Further the cable management system is fully customizable to fit nearly any type of electronic enclosure.

The improved cable management system may comprise multiple embodiments. In one embodiment, the improved cable management system uses a closed cell foam to prevent air bypass. In another embodiment, the improved cable management system uses open cell foam that will allow the improved cable management system to act like a filter by allowing air into the system reducing system impedance while preventing dust ingress.

### BRIEF DESCRIPTION OF THE DRAWINGS

FIG. 1A depicts a first embodiment of a known cable management system.

FIG. 1B depicts a second embodiment of a known cable management system.

FIG. 1C depicts a third embodiment of a known cable management system.

FIG. 2A depicts a front side view of an embodiment of the cable management system of the present disclosure, including a baffle and corresponding frame.

FIG. 2B depicts a perspective overhead view of an embodiment of a baffle without a corresponding frame.

FIG. 3A depicts an embodiment of the cable management system having vertical cable inlet channels.

FIG. 3B depicts an embodiment of the cable management system having perforated vertical cable inlet channels.

FIG. 4A depicts an embodiment of the cable management system having a horizontal cable inlet channel.

FIG. 4B depicts an embodiment of the cable management system having a perforated horizontal cable inlet channel.

FIG. 5A depicts an embodiment of the cable management system having both vertical and horizontal cable inlet channels.

FIG. 5B depicts an embodiment of the cable management system having perforated vertical and horizontal cable inlet channels.

FIG. 6A depicts an alternative embodiment of the cable management system having perforated vertical and horizontal cable inlet channels.

FIG. 6B depicts an embodiment of the cable management system having vertical cable inlet channels which extend to one surface of the perimeter wall.

FIG. 6C depicts an embodiment of the cable management system having multiple arrangements of vertical and horizontal cable inlet channels. The cable management system depicts a first set of vertical inlet channels extending to one surface of the perimeter wall; a second set of vertical inlet channels disposed within the boundary formed by the perimeter wall; and a third set of inlet channels with intersecting vertical and horizontal inlet channels.

FIG. 6D depicts an embodiment of the cable management system having intersecting vertical and horizontal inlet channels disposed within the boundary of the perimeter wall.

FIG. 6E depicts a circular embodiment of the cable management system having a plurality of inlet channels intersecting at the center point of the circular baffle and disposed within the boundary of the perimeter wall.

FIG. 7A depicts a rear side view of an embodiment of the cable management system including a baffle and corresponding frame.

FIG. 7B depicts a font side view of FIG. 7A.

FIG. 7C depicts a rear side view of an embodiment of the cable management system wherein the baffle and frame each comprise separable top and bottom portions.

FIG. 7D depicts a front side view of FIG. 7C.

FIG. 8A depicts a rear side view of a baffle with a piece of mounting tape disposed along the rear surface of the baffle.

FIG. 8B depicts a perspective view of a baffle with a piece of mounting tape disposed along a surface of the perimeter wall.

FIG. 8C depicts a front side view of a baffle with a strips of mounting tape disposed along an upper and lower surface of the perimeter wall.

FIG. 9A depicts a rear side view of an embodiment of the cable management system including a frame disposed along the rear surface of the baffle to form an outer boundary for intersecting vertical and horizontal inlet channels.

FIG. 9B depicts a rear side view of an embodiment of the cable management system including a frame disposed along the rear surface of the baffle to form an outer boundary for horizontal inlet channels.

FIG. 9C depicts a rear side view of an embodiment of the cable management system including a frame disposed along the rear surface of the baffle to form a boundary for the vertical inlet channels.

FIG. 9D depicts a rear side view of an embodiment of the cable management system including a frame disposed along the rear surface of the baffle to form a boundary for the vertical inlet channels.

FIG. 9E depicts a rear side view of an embodiment of the cable management system including a frame disposed along the rear surface of the baffle to form a boundary for the vertical inlet channels.

FIG. 9F depicts a rear side view of an embodiment of the cable management system including a frame disposed along the rear surface of the baffle to form a boundary for a plurality of arrangements of inlet channels.

FIG. 9G depicts a rear side view of an embodiment of the cable management system including a frame disposed along the rear surface of the baffle to form a boundary for intersecting vertical and horizontal inlet channels.

FIG. 9H depicts a rear side view of an embodiment of a circular cable management system including a frame disposed along the rear surface of the baffle to form a boundary for inlet channels which intersect at the center point of the circular cable management system.

FIG. 10 depicts an embodiment of the cable management system and frame in a flexed configuration.

FIG. 11 depicts an embodiment of the cable management system and frame with a plurality of cables passing therethrough.

FIG. 12 depicts an embodiment of the cable management system and frame, wherein a mounting portion of the frame extends toward the front side of the cable management system.

FIG. 13 depicts a perspective view of an embodiment of the cable management system.

FIG. 14 depicts a perspective view of an embodiment of the cable management system.

FIG. 15 depicts a perspective view of an embodiment of the cable management system.

FIG. 16 depicts a perspective view of an embodiment of a circular cable management system.

### DETAILED DESCRIPTION

This disclosure as a whole may be best understood by reference to the following detailed description when read in conjunction with the accompanying drawings, drawing descriptions, abstract, background, field of disclosure, and associated headings. Identical reference numbers when found on different figures identify the same elements or a functionally equivalent element. The elements listed in the abstract are not referenced but nevertheless refer by association to the elements of the detailed description and associated disclosure.

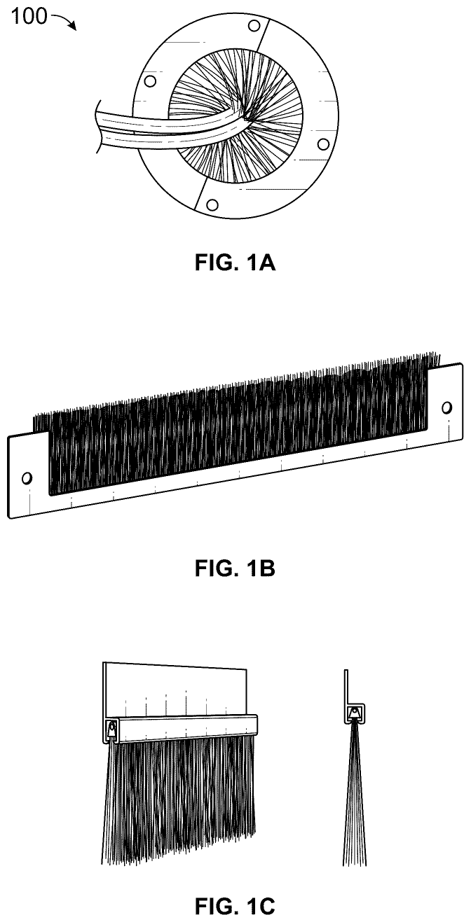

FIGS. 1A-1C discloses examples of known cable management systems 100 such as grommet type, fixed brush, and brush strip devices. These cable management systems are limited to fixed dimensions. While these cable management systems 100 can be cut to a desired length, they are not otherwise adjustable and provide solely linear solutions. The known cable management systems 100 have limited cable path options and provide limited, if any, reduction in system impedance.

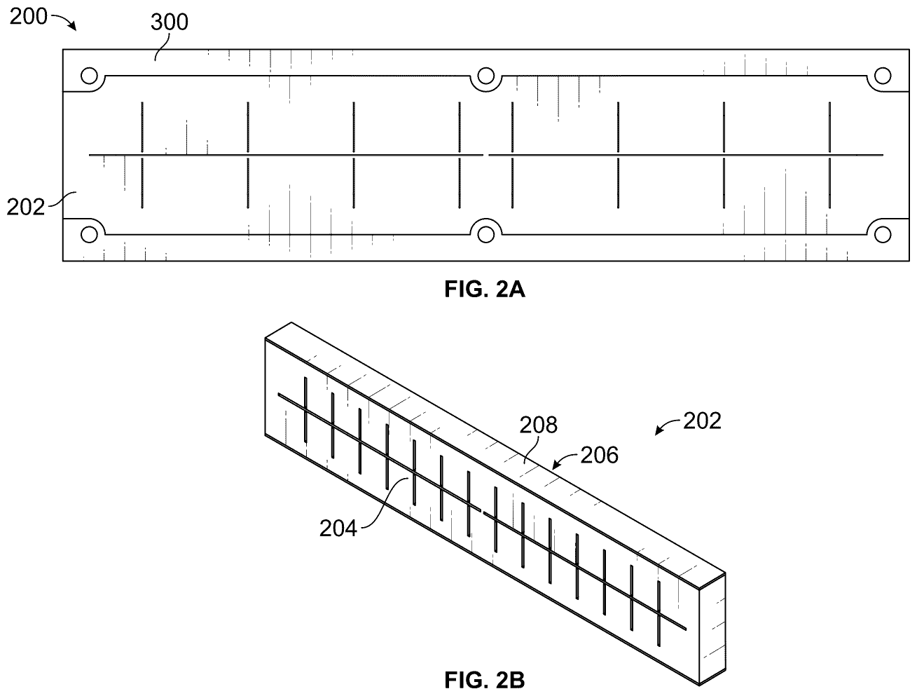

Starting with FIG. 2, the new cable management system 200 as disclosed herein uses a foam technology to promote improved cable path optimization (which in turn reduces air bypass and cable strain) and acts as a filter to reduce system impedance.

FIGS. 2A through 2B depict an improved cable management system 200. The improved cable management system 200 can be configured to any desired shape (including, but not limited to three dimensional triangles, ovals, circles, and polygons). The improved cable management system 200 can be shaped to fit curved surfaces, flexed to fit obstructed installations, or notched to fit any desired system architecture. In the preferred embodiment, the improved cable management system 200 comprises a flexible baffle 202 having a top face (or front surface) 204, bottom face (or rear surface) 206, and/or a perimeter wall 208 forming a thickness there between the top 204 and bottom face 206.

In an embodiment, the flexible baffle 202 is comprised of a material having a high degree of flexibility, such as, but not limited to polyurethane. Unlike the known cable management systems, the flexible baffle 202 is designed to fit within any type of electronic enclosure (whether linear or curved). In an embodiment, the flexible baffle 202 meets UL flammability standards with a UL94 (HF-1 or V0) rating.

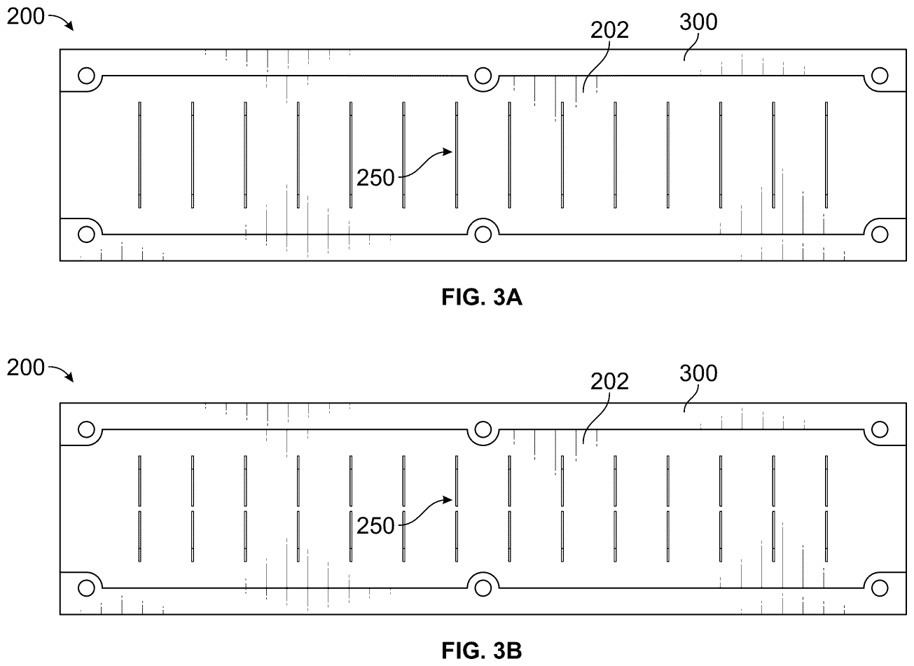

The flexible baffle 202 is comprised of a desired patten of cable inlets 250 (shown more specifically in FIG. 3). The cable inlets 250 can be arranged in any manner suitable to provide a channel for cables and wires to pass through the improved cable management system 200 and into the electronic enclosure. The cable inlets 250 limit air bypass through the improved cable management system 200 into the enclosure. In a preferred embodiment, specific cables and wires are passed through specific cable inlets 250 to prevent “grouping” of wires. And the cable inlets 250 compress around each cable or wire to reduce the amount of void space (and reduce air bypass). In traditional cable brush systems, wires bunch or “group” together and form large void spaces around the “grouped” wires (and increase air bypass).

In an embodiment, the cable inlets 250 form a series of vertical channels placed side by side such as in FIG. 3A. As shown, the cable inlets 250 are disposed within the perimeter wall 208 of the baffle 202 (and do not extend through the perimeter wall 208). A user may insert cabling through the cable inlets 250 and the cable inlets form a seal around the cables to limit ingress of dust through the cable management system 200. In an embodiment, the cable inlets 250 form a series of perforated vertical channels placed side by side such as in FIG. 3B. The perforated channels may limit air bypass in locations where no cables or wires pass through the flexible baffle 202.

In the embodiments depicted in FIGS. 3A and 3B, the baffle 202 is affixed to the frame 300 and the frame 300 may be attached to the entrance of electrical enclosure.

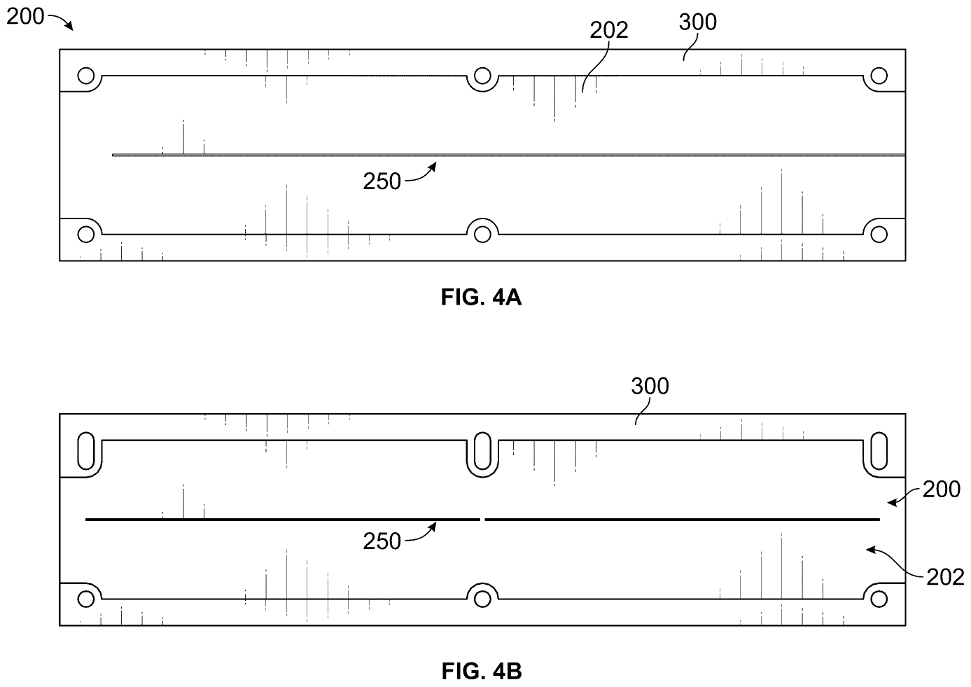

In an embodiment, the cable inlets 250 form a horizontal channel on the flexible baffle 202 as in FIG. 4A. As shown in FIG. 4A, the horizontal cable inlet 250 extends through one side of the perimeter wall 208. In other embodiments, such as FIG. 4B, the cable inlet 250 is disposed within the perimeter wall 208 of the baffle 202 (and does not extend through the perimeter wall 208). A user may insert cabling through the cable inlets 250 and the cable inlets 250 form a seal around the cables to limit ingress of dust through the cable management system 200. In an embodiment, the cable inlets 250 form a perforated horizontal channel as in FIG. 4B. The perforated channels limit air bypass in locations where no cables or wires pass through the flexible baffle 202.

In the embodiments depicted in FIGS. 4A and 4B, the baffle 202 is affixed to the frame 300 and the frame 300 may be attached to the entrance of electrical enclosure.

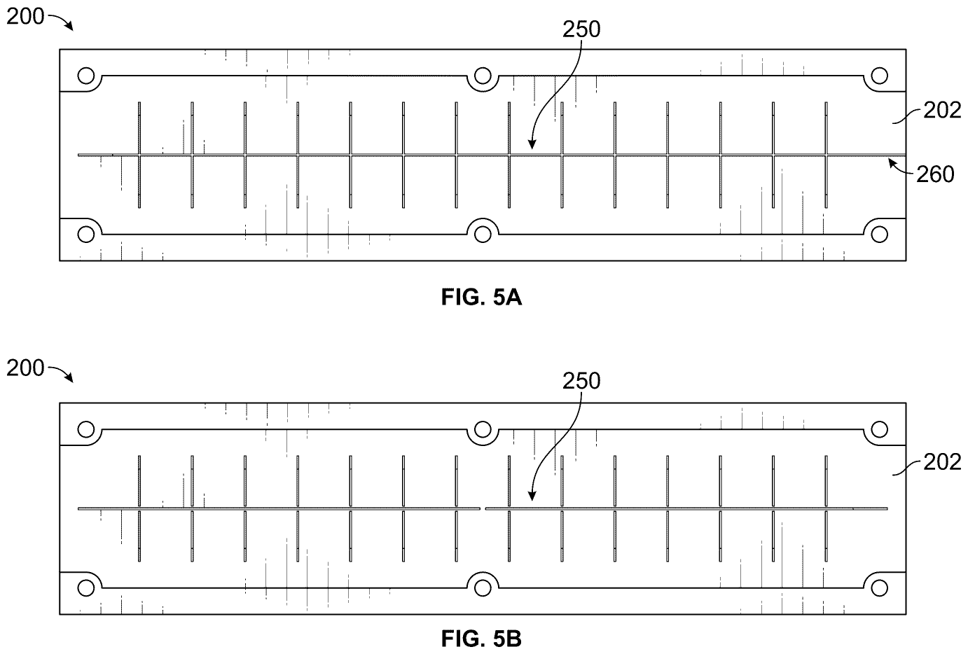

In an embodiment, the cable inlets 250 form a series of cross hairs (i.e., vertical channels intersecting with horizontal channels) as depicted in FIG. 5A. In the embodiment depicted in FIG. 5A, the flexible baffle 202 also includes an installation inlet 260 proximate an edge of the flexible baffle 202. The installation inlet 260 allows the improved cable management system 200 to be installed and removed from an electronic enclosure without disconnecting any cables or wires. In an embodiment, the cable inlets 250 form a series of perforated cross hairs as shown in FIG. 5B. The perforated channels limit air bypass in locations where no cables or wires pass through the flexible baffle 202. The embodiment in FIG. 5B depicts cable inlets 250 disposed within the perimeter wall 208 of the baffle 202 (such that the cable inlets 250 do not extend through the perimeter wall 208). A user may insert cabling through the cable inlets 250 and the cable inlets 250 form a seal around the cables to limit ingress of dust through the cable management system 200.

In the embodiments depicted in FIGS. 5A and 5B, the baffle 202 is affixed to the frame 300 and the frame 300 may be attached to the entrance of electrical enclosure.

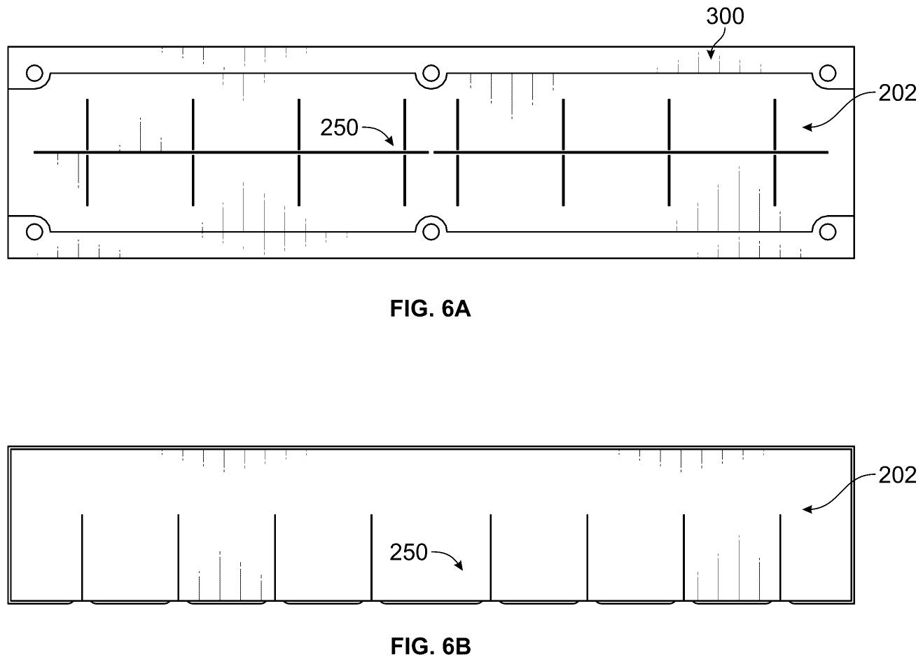

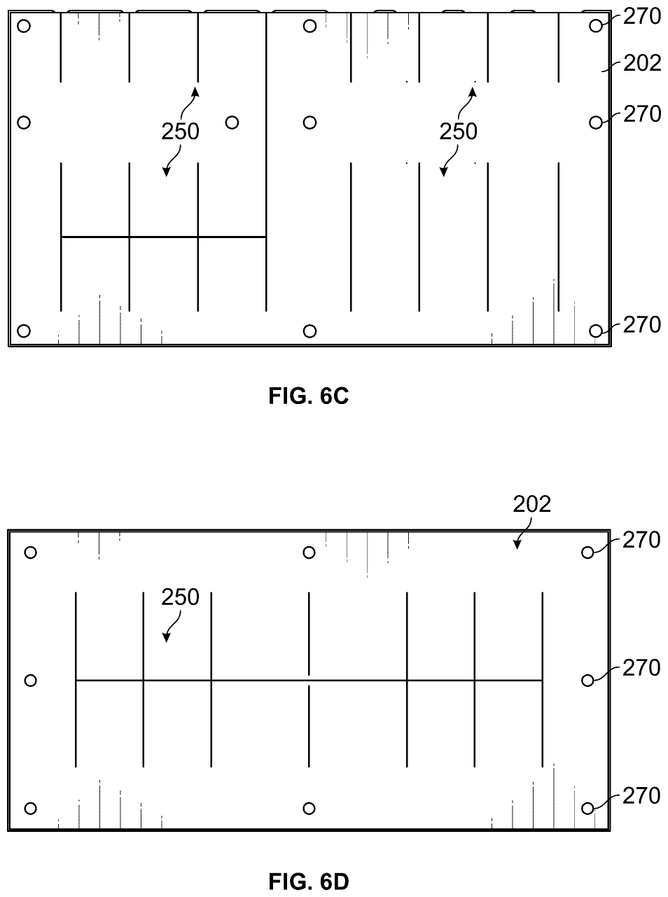

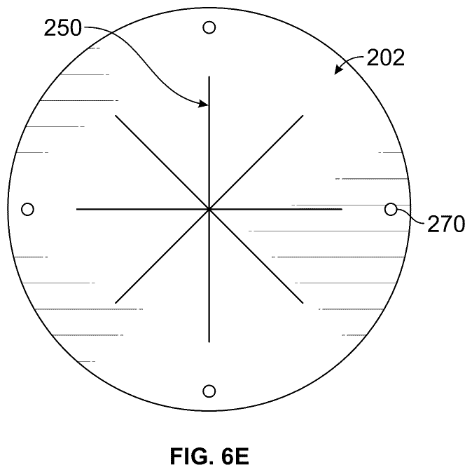

FIGS. 6A through 6E depict a plurality of alternative embodiments of the cable management system 200, namely cable management systems 200 comprising different styles of cable inlets 250. Each of FIGS. 6A through 6E depict a baffle 202, corresponding frame 300, and cable inlets 250. FIG. 6A depicts a cable management system 200 wherein the baffle 202 includes cable inlets 250 comprising a plurality of perforated cross hairs. In FIG. 6A, the cable inlets 250 are disposed within the perimeter wall 208 of the baffle 202 (such that the cable inlets 250 do not extend through the perimeter wall 208). FIG. 6B depicts a cable management system 200 wherein the baffle 202 comprising a plurality of vertical cable inlets 250. In FIG. 6B, the vertical cable inlets 250 extend through one surface of the perimeter wall 208. This allows the improved cable management system 200 to be installed and removed from an electronic enclosure without disconnecting any cables or wires. FIG. 6C depicts a cable management system 200 incorporating both of the foregoing types of cable inlets 250 depicted in FIGS. 6A and 6B. This cable management system 200 depicts vertical cable inlets 250 which extend through one surface of the perimeter wall 208. In addition, this cable management system 200 includes a plurality of cross-hair cable inlets 250 and vertical inlets 250, each of which are disposed within the perimeter wall 208. The arrangement of FIG. 6C provides a user with a plurality of options and includes the benefits of each type of cable management system 200 in FIGS. 6A and 6B. FIG. 6D depicts a cable management system 200 wherein the baffle 202 includes cable inlets 250 comprising a plurality of cross hairs. In FIG. 6D, the cable inlets 250 are disposed within the perimeter wall 208 of the baffle 202 (such that the cable inlets 250 do not extend through the perimeter wall 208). FIG. 6E depicts a circular cable management system 200 having a circular baffle 202. Each of the cable inlets 250 are disposed within the perimeter wall 208 of the baffle 202 (such that the cable inlets 250 do not extend through the perimeter wall 208) and converge at the center point of the circular baffle 202. FIGS. 6C through 6E include a plurality of apertures 270 which may extend through the baffle 202 and/or frame 300 for mounting the cable management system 200.

In an embodiment, the flexible baffle 202 is comprised of an open-cell foam. In this embodiment, the foam baffle 202 acts as a filter which allows airflow to and from the electronic enclosure, but prevents dust ingress. The open-cell foam can help reduce the system impedance when using the improved cable management system 200.

In an embodiment, the flexible baffle 202 is comprised of a non-reticulated open-cell foam. In this embodiment, the foam baffle 202 acts as a seal to prevent both airflow and dust ingress through an electronic enclosure.

In an embodiment, the length and width of the top 204 and bottom face 206 can be up to 24 inches by 48 inches. In an embodiment, the thickness for a non-reticulated open-cell foam flexible baffle 202 can range from ¼ inch to 1 inch and the thickness for an open cell flexible baffle 202 can range from ¼ inch to ½ inch.

In the preferred embodiment, the foam baffle 202 has at least a 10-year lifecycle when subjected to the ASTM F 1980-21 accelerated aging test.

For each of the baffles 202 described herein, each set of plurality of inlets 250 may be comprised of between 2 and 20 narrow slits through which a user may wedge cables and wiring. In a preferred embodiment, the plurality of inlets 250 comprises between 4 and 8 narrow slits (whether arranged vertically, horizontally, or otherwise).

In embodiments, the cable management system 200 includes a frame 300 disposed on either the top surface 204 or bottom surface 206 of the foam baffle 202. In an embodiment, the frame 300 is comprised of a polypropylene material and is flexible. The frame 300 covers at least a portion of the applied-to surface 204, 206 and includes mounting holes 302 to fasten the improved cable management system 200 to an electronic enclosure. The frame 300 includes at least one groove (or opening) 306 to allow cables and wires to pass through the foam baffle 202 and frame 300. In other alternative embodiments, the frame 300 may be comprised of a rigid material.

The improved cable management system 200 with (or without) the frame 300 is designed to be installed in all types of electronic enclosures, including curved surfaces and partially obstructed installation paths.

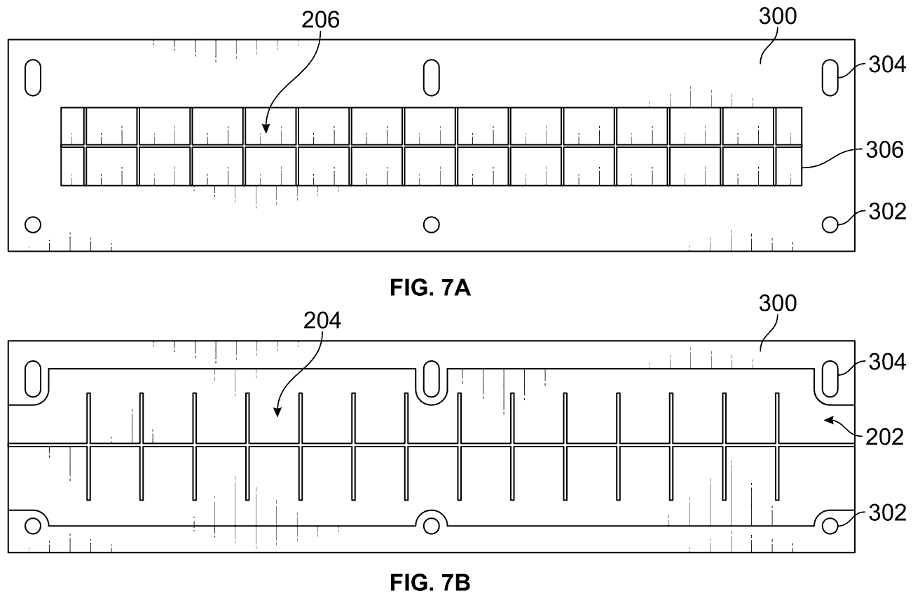

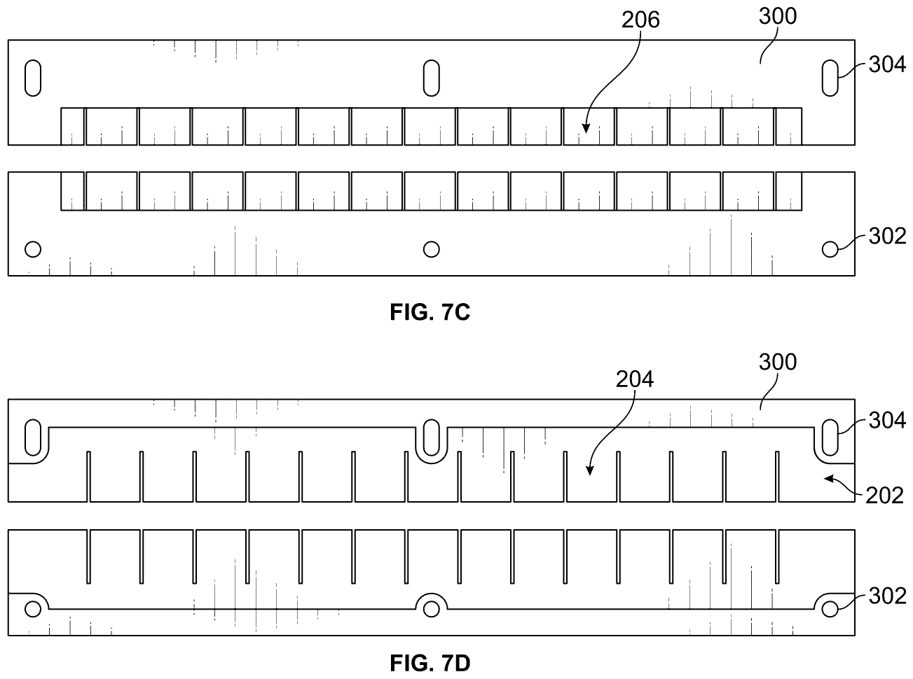

FIGS. 7A through 7B depict an embodiment of the cable management system 200 wherein each of the baffle 202 and frame 300 are unitary components. In FIGS. 7A and 7B, the baffle 202 is comprised of a single unitary piece of material and the frame 300 is comprised of a single unitary piece of material. The baffle 202 is secured to the frame 300 and is used to cover the entry to an electrical enclosure. The frame 300 includes mounting holes 302 and slotted mounting holes 304. The slotted mounting holes 304 allow for additional versatility, such that a user can loosen fasteners and shift the cable management system 200 up or down to a desired position.

As shown in FIGS. 7A and 7B, the frame is mounted to the rear surface 206 of the baffle 202 (opposite the front surface 204).

FIGS. 7C and 7D depict an alternative embodiment of the cable management system 200 wherein the baffle 202 and frame 302 are each comprised of multiple parts. As depicted in FIGS. 7C and 7D, the baffle 202 comprises a top portion and bottom portion and the frame 302 comprises a top portion and bottom portion. The baffle 202 is secured to the frame 300 and is used to cover the entry to an electrical enclosure. The frame 300 includes mounting holes 302 and slotted mounting holes 304. The slotted mounting holes 304 allow for additional versatility, such that a user can loosen fasteners and shift the cable management system 200 up or down to a desired position. FIGS. 7C and 7D depict the frame 300 and baffle 202 in an open position. A user can move the cable management system 200 into a “closed” position such that it looks like the cable management systems in FIGS. 7A and 7B by adjusting the fasteners applied to the slotted mounting holes 304 and moving the frame 300 up or down as desired.

As shown in FIGS. 7C and 7D, the frame is mounted to the rear surface 206 of the baffle 202 (opposite the front surface 204).

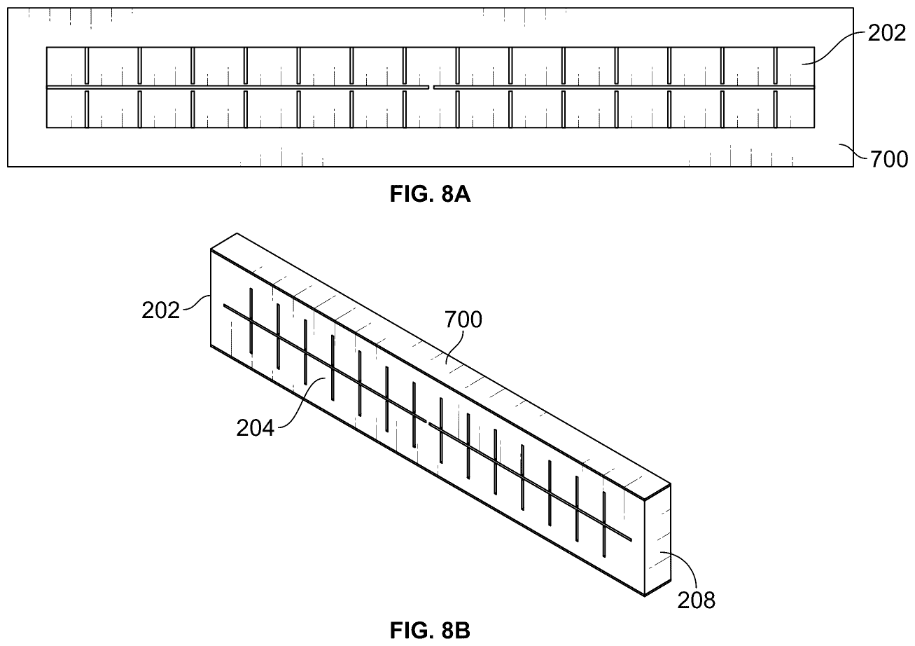

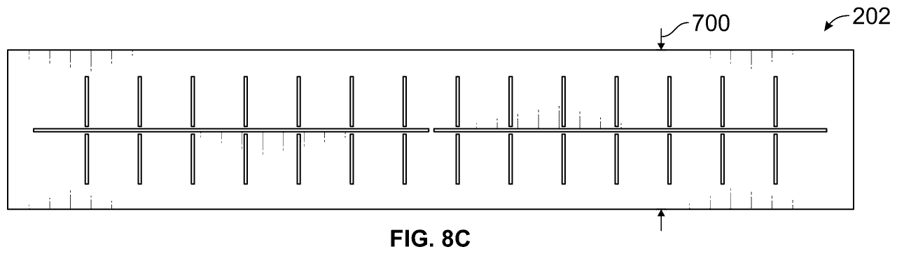

FIGS. 8A through 8C depict an alternative embodiments of the cable management system 200 without frames 300. These embodiments use alternative means to mount the improved cable management system 200 within an electronic enclosure. Specifically, FIG. 8A uses double-sided mounting tape 700 on the face 204, 206 of the baffle 202. Alternative means such as hook and loop tape may be used. FIGS. 8B and 8C depict a baffle 202 with mounting tape 700 along the perimeter wall 208 of the baffle 202. Alternative means such as hook and loop tape may be used.

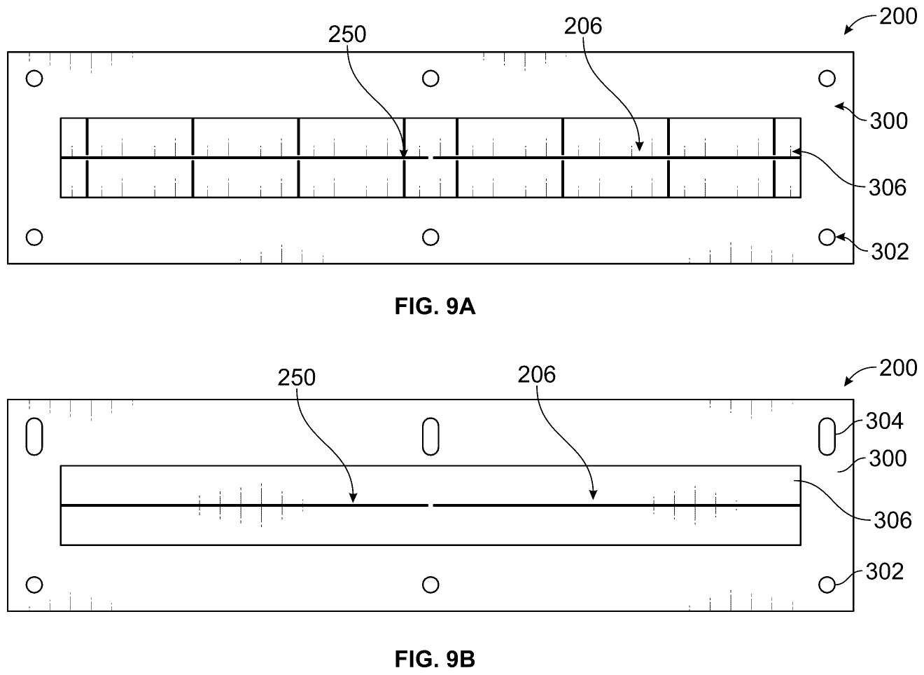

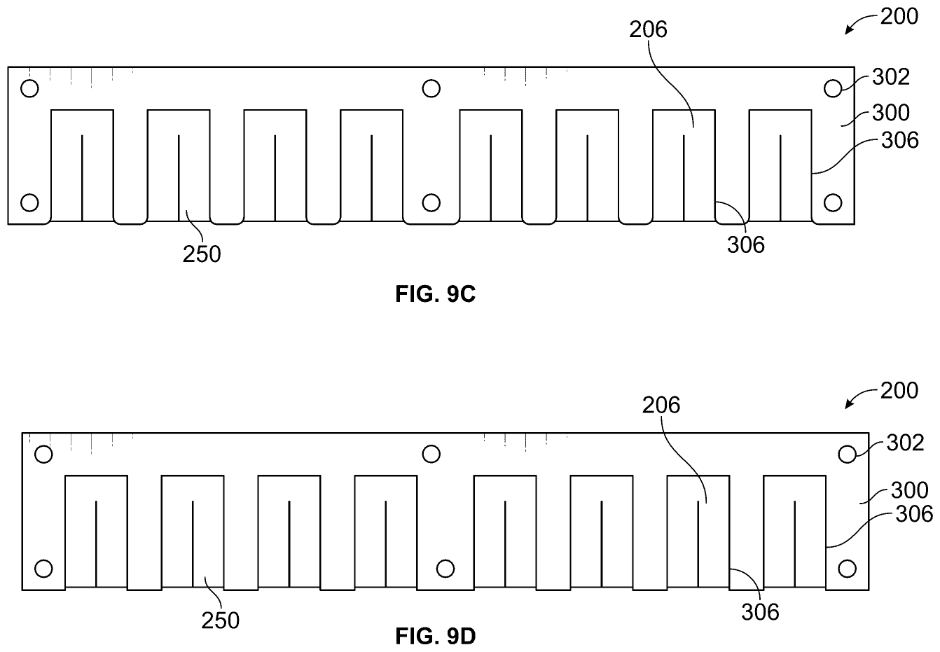

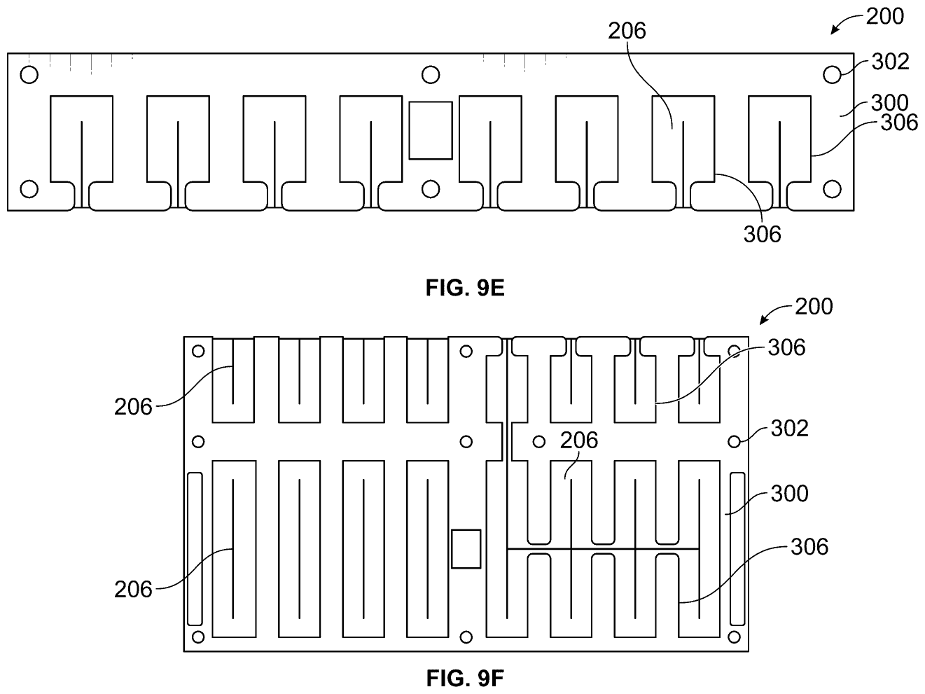

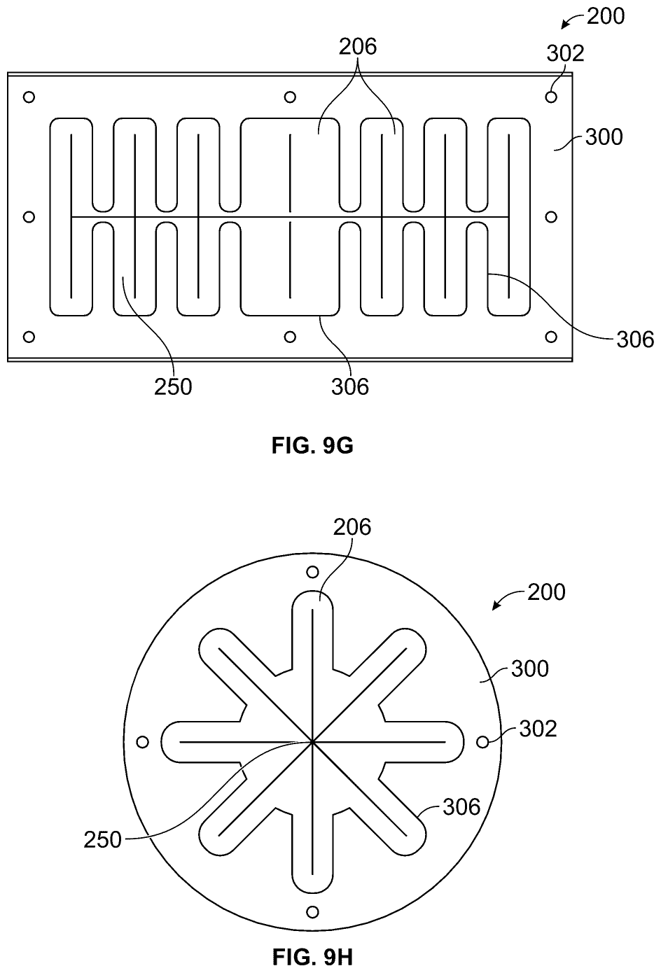

Customized frames 300 can be used in connection with the improved cable management systems 200 disclosed herein. These customized frames 300 can be arranged in any desired pattern. FIGS. 9A through 9H depicts embodiments of a customized frame 300. The customized frame 300 includes a plurality of openings 306 along various portions of the cable inlets 250. The customized frames 300 provide a user with the ability to create customized entry points for wires and cables at the mouth of an electronic enclosure. The custom frames 300 provide further optimization to allow any desired wires and cables into the enclosure while limiting air bypass. The custom frames 300 can be built to match desired specifications (such as placement of wires in desired locations at the mouth of the enclosure). In addition, the custom frames 300 allow for custom cable inlets 250 fitted to match the specification of particular wires and cables.

In traditional cable brush systems, the location of wires is random and in many instances wires will bunch together and create (in effect) one large diameter wire, creating larger void spaces. The custom frames 300 and foam baffle 202 remedy this limitation.

FIGS. 9A-9B depict a customized frame 300 wherein the frame 300 is disposed on the bottom surface 206 of the foam baffle 202. In FIGS. 9A-9B, the frame 300 covers at least a portion of the applied-to surface 206. As shown, the frame 300 may partially cover the bottom surface 206 of the baffle 202 and form a rectangular enclosure with a rectangular opening 306. The rectangular opening 306 allows cables and wires to pass through the foam baffle 202. In FIG. 9A, the cable inlets 250 of the baffle 202 form a series of cross hairs that are disposed within the boundary of the perimeter wall 208 of the baffle 202. In other embodiments, such as FIG. 9B, the cable inlets 250 of the baffle 202 form a horizontal channel and extend through both sides of the perimeter wall 208 of the baffle 202 and the frame 300. In addition, in FIG. 9A, the frame 300 includes mounting holes 302 to fasten the improved cable management system 200 to an electronic enclosure. In other embodiments, such as FIG. 9B, the frame 300 includes both mounting holes 302 and slotted mounting holes 304. The slotted mounting holes 304 allow for additional versatility, such that a user can loosen fasteners and shift the cable management system 200 up or down to a desired position.

FIG. 9C depicts a customized frame 300 wherein the frame 300 is disposed on the bottom surface 206 of the foam baffle 202. In FIG. 9C, the frame 300 covers at least a portion of the applied-to surface 206. As shown, the frame 300 may partially cover the bottom surface 206 of the baffle 202 with spaced supporting portions extending from a top portion of the frame 300, where each supporting portion is separated by a gap to create vertical openings 306. In FIG. 9C, the corners of the supporting portions are flat. As shown in FIG. 9D, the corners of the supporting portions are rounded. In other embodiments, such as FIG. 9E, the supporting portions are shaped to form inverted “T's” such that the opening 306 near the bottom of the frame 300 is narrower than the opening 306 near the top of the frame 300. The vertical openings 306 disposed between the supporting portions to allow cables and wires to pass through the foam baffle 202. In FIG. 9C, the baffle 202 of the frame 300 comprises a plurality of vertical cable inlets 250 that extend through the perimeter wall 208 of the baffle 202. In addition, in FIG. 9C, the frame 300 includes mounting holes 302 to fasten the improved cable management system 200 to an electronic enclosure.

FIG. 9F depicts a customized frame 300 wherein the frame 300 is disposed on the bottom surface 206 of the foam baffle 202. In FIG. 9F, the frame 300 covers at least a portion of the bottom surface 206. As depicted, the frame 300 of FIG. 9F comprises a plurality of openings 306 to allow cables and wires to pass through the foam baffle 202, including the types of openings 306 disclosed in FIGS. 9A through 9E. The frame 300 is fitted to match the various version of inlets 250 described herein. In addition, in FIG. 9F, the frame 300 includes mounting holes 302 to fasten the improved cable management system 200 to an electronic enclosure.

FIG. 9G depicts a customized frame 300 wherein the frame 300 is disposed on the bottom surface 206 of the foam baffle 202. In FIG. 9G, the frame 300 covers at least a portion of the bottom surface 206. The frame 300 partially covers the baffle 202 to form rectangular openings 306 along the rear surface 206 of the baffle 202. Spaced apart supporting portions extend from the top and bottom portions of the frame 300 to create the rectangular openings 306. The rectangular openings 306 allow cables and wires to pass through the foam baffle 202. In FIG. 9G, the baffle 202 of the frame 300 comprises a plurality of vertical cable inlets 250 which intersects with a horizontal cable inlet 250 to allow cables and wires to pass through. In addition, in FIG. 9G, the frame 300 includes mounting holes 302 to fasten the improved cable management system 200 to an electronic enclosure.

FIG. 9H depicts a circular customized frame 300 wherein the frame is disposed on the bottom surface 206 of the foam baffle 202. In FIG. 9H, the frame 300 covers at least a portion of the bottom surface 206. The circular frame 300 covers at least a portion of the bottom surface 206 of the baffle 202 to form an opening 306. In addition, spaced apart supporting portions extend from the circular frame 300 to provide added stability to the baffle 202. In embodiments, such as FIG. 9H, the supporting may be tapered. In FIG. 9H, the baffle 202 comprises a plurality of cable inlets 250 that converge at the center point of the baffle 202. In addition, in FIG. 9H, the circular frame 300 includes mounting holes 302 to fasten the improved cable management system 200 to an electronic enclosure.

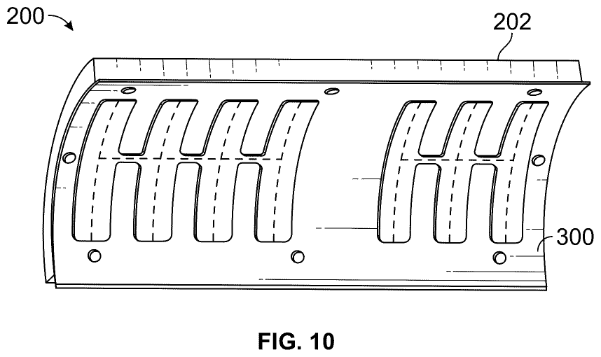

In an embodiment, the frames 300 are flexible, as depicted in FIG. 10. While FIG. 10 solely depicts one style of frame, each of the frames described herein may be configured to have flexible frames. Together the frames 300 with the baffle 202 are flexible enough for use with any desired cabinet, cable pass through, or electronic enclosure. Both framed and unframed baffles 202 allow for mounting on both flat and curved surfaces of an electronic enclosure. This flexibility provides dexterity to install the improved cable management system 200 in any electronic enclosure.

Each of the above-described elements of the improved cable management system 200 (including any of the different variations of the channel inlets 250, variations of frames 300, and baffles 202) can be combined to create a desired cable management system 200.

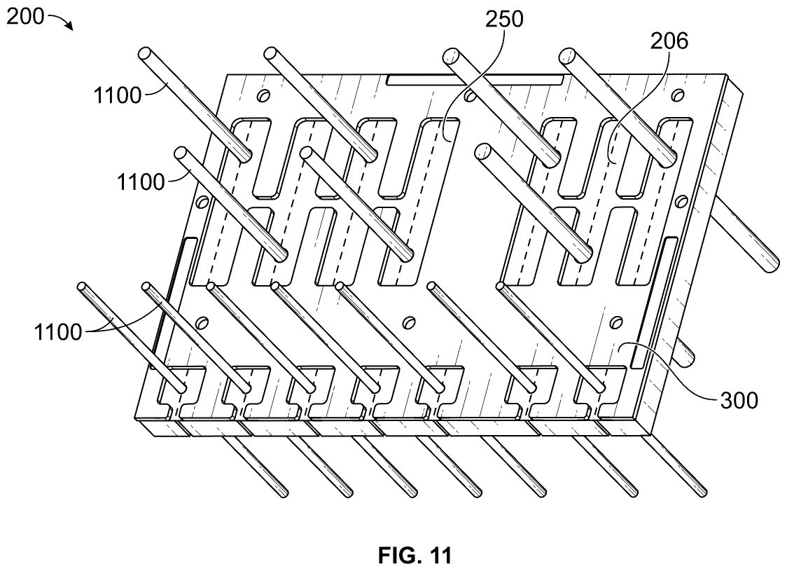

FIG. 11 depicts an embodiment of the cable management system 200 in use, such that a plurality of cables 1100 pass through a plurality of inlets cable 250 and corresponding openings 306 in the frame 300.

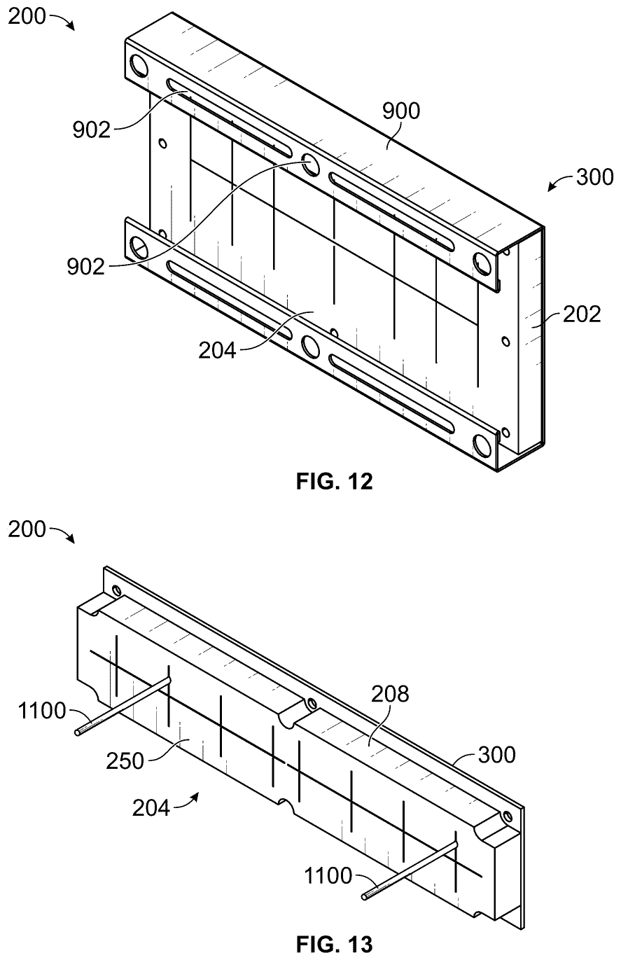

FIG. 12 depicts an embodiment of the cable management system 200 with a frame 300 which includes a mounting rack 900 surrounding a portion of the front surface 204 of the baffle 202. The mounting track 900 comprises a plurality of apertures 902 to provide an alternative mounting position for the cable management system 200.

FIGS. 13-16 depict perspective views of embodiments of the cable management system 200 with a frame 300 connected to the baffle 202. In addition, in FIGS. 13-16, a plurality of cables 1100 pass through a plurality of inlets 250. FIG. 13 provides a perspective view of a cable management system 200 depicted in FIGS. 6A and 9A. FIG. 13 depicts the front surface 204 of the baffle, plurality of inlets 250, perimeter wall 208 and frame 300 described in connection with the cable management system 200 depicted in FIGS. 6A and 9A.

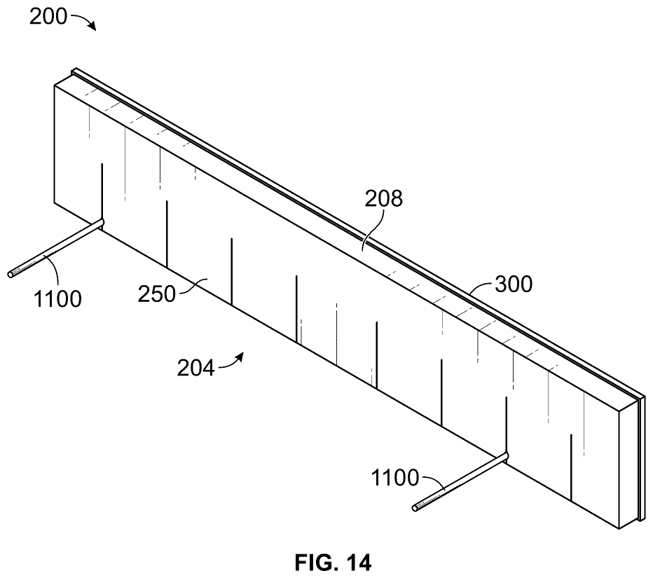

FIG. 14 provides a perspective view of the cable management system 200 depicted in FIGS. 6B and 9E. FIG. 14 depicts the front surface 204 of the baffle 202, plurality of inlets 250, perimeter wall 208 and frame 300 described in connection with the cable management system 200 depicted in FIGS. 6B and 9E.

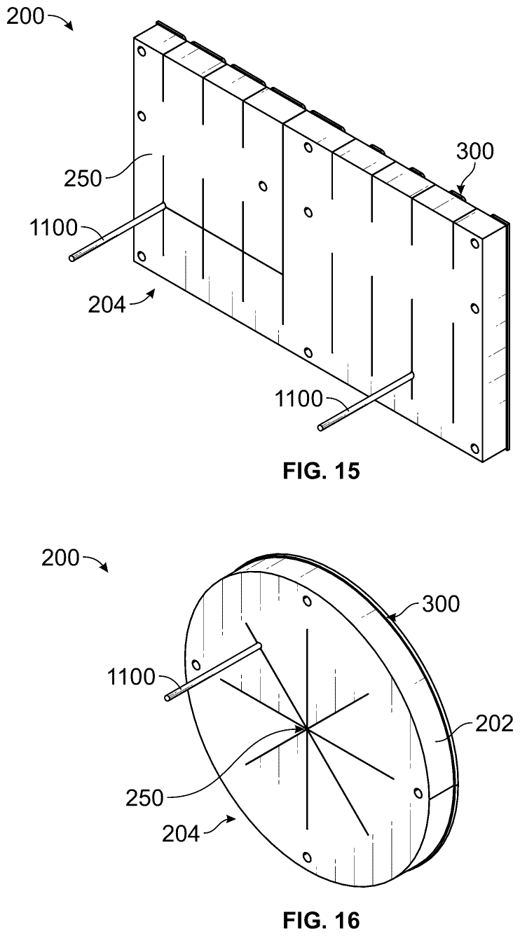

FIG. 15 provides a perspective view of the cable management system 200 depicted in FIGS. 6C and 9F. FIG. 15 depicts the font surface 204 of the baffle 202, plurality of inlets 250, perimeter wall 208 and frame 300 described in connection with the cable management system 200 depicted in FIGS. 6C and 9F.

FIG. 16 provides a perspective view of the cable management system 200 depicted in FIGS. 6E and 9H. FIG. 16 depicts the front surface 204 of the circular baffle 202, plurality of inlets 250, perimeter wall 208 and frame 300 described in connection with the cable management system 200 depicted in FIGS. 6E and 9H.

The foregoing examples have been provided merely for the purpose of explanation, and are in no way to be construed as limiting of the present invention disclosed herein. While the invention has been described with reference to various embodiments, it is understood that the words, which have been used herein, are words of description and illustration, rather than words of limitation. Further, although the invention has been described herein with reference to particular means, materials, and embodiments, the invention is not intended to be limited to the particulars disclosed herein; rather, the invention extends to all functionally equivalent structures, methods and uses, such as are within the scope of the appended claims. Those skilled in the art, having the benefit of the teachings of this specification, may affect numerous modifications thereto and changes may be made without departing from the scope and spirit of the invention in its aspects.

Any other undisclosed or incidental details of the construction or composition of the various elements of the disclosed embodiment of the present invention are not believed to be critical to the achievement of the advantages of the present invention, so long as the elements possess the attributes needed for them to perform as disclosed. Certainly, one skilled in the field would be able to conceive of a wide variety of alternative configurations and successful combinations thereof. The selection of these and other details of construction are believed to be well within the ability of one of even rudimental skills in this area, in view of the present disclosure. Illustrative embodiments of the present invention have been described in considerable detail for the purpose of disclosing a practical, operative structure whereby the invention may be practiced advantageously. The designs described herein are intended to be exemplary only. The novel characteristics of the invention may be incorporated in other structural forms without departing from the spirit and scope of the invention. The invention encompasses embodiments both comprising and consisting of the elements described with reference to the illustrative embodiments. All technical terms shall take on their customary meaning as established by the appropriate technical discipline utilized by those normally skilled in that particular art area.

What is claimed is:

1. A cable management system comprising:
a baffle having a front surface, a rear surface, and a perimeter wall extending therebetween, the baffle comprised of a flexible polyurethane foam;
a plurality of inlets extending through the front surface and rear surface of the flexible baffle, wherein the inlets are arranged in a desired pattern to secure cables within the inlets;
a frame secured to the rear surface of the baffle, the frame comprised of a polypropylene material and having an outer boundary greater than the baffle;
wherein the frame comprises a plurality of mounting holes to mount the frame to an electronic enclosure;
wherein the frame comprises an opening to facilitate passage of cables through the flexible baffle and frame;

2. The cable management system of claim 1, wherein the baffle and frame are comprised of a cylindrical shape.

3. The cable management system of claim 2, wherein the plurality of inlets comprise a series of narrow slits which are disposed within boundary formed by the perimeter wall and intersect at the center point of the front surface of the cylindrically shaped baffle.

4. The cable management system of claim 3, wherein the plurality of inlets comprise n narrow slits, wherein n is an integer between 4 and 8.

5. The cable management system of claim 4, wherein the frame is configured such that the plurality of inlets on the rear surface of the baffle are exposed to provide passage for cables.

6. The cable management system of claim 5, wherein the frame includes supporting extensions extending at least partially between the plurality of inlets along the rear surface of the baffle.

7. The cable management system of claim 1, wherein the baffle and frame are comprised of a quadrilateral shape.

8. The cable management system of claim 7, wherein the plurality of inlets are disposed within the boundary formed by the perimeter wall of the baffle and comprise a series of vertically oriented slits which intersect with at least one horizontally oriented slit.

9. The cable management system of claim 8, wherein the plurality of inlets comprises a series of n vertically oriented slits, wherein n is an integer between 4 and 8.

10. The cable management system of claim 9, wherein the frame is configured such that the plurality of inlets on the rear surface of the baffle are exposed to provide passage for cables.

11. The cable management system of claim 10, wherein the frame includes supporting extensions extending at least partially between the plurality of inlets along the rear surface of the baffle.

12. The cable management system of claim 7, wherein the plurality of inlets extend from within the boundary formed by the perimeter wall of the baffle and through one surface of the perimeter wall, the plurality of inlets comprising vertically oriented slits.

13. The cable management system of claim 12, wherein the frame is configured such that the plurality of inlets on the rear surface of the baffle are exposed to provide passage for cables.

14. The cable management system of claim 7, wherein the plurality of inlets comprise:
a series of vertically oriented slits which intersect with at least one horizontally oriented slit, the foregoing disposed within the boundary formed by the perimeter wall; and
a series of vertically oriented slits extending from within the boundary formed by the perimeter wall through one surface of the perimeter wall.

15. The cable management system of claim 1, wherein the baffle further comprises a plurality of apertures in coaxial alignment with the mounting holes of the frame which are used to mount the cable management system to the electronics enclosure.

16. The cable management system of claim 1, wherein the flexible polyurethane foam of the baffle secures cables in place by compressing the cables disposed within the plurality of inlets.

17. A cable management system comprising:
a baffle having a plurality of inlets extending therethrough, and an outer frame secured to a surface of the baffle, the outer frame having a larger outer boundary than the baffle;
wherein the frame has a plurality of apertures to mount the cable management system to an electronic enclosure; and
wherein the inlets provide a passageway for cables to pass through the baffle and an opening of the frame.

18. A method of using the cable management system, the cable management system comprising a baffle having a plurality of inlets extending therethrough, an outer frame secured to a surface of the baffle, the outer frame having a larger outer boundary then the baffle, and the inlets provide a passageway for cables to pass through the baffle and an opening of the frame, the method comprising the steps of:
securing a plurality of apertures disposed along the frame to an electronic enclosure; and
passing cables through the inlets of the baffle and out the opening of the outer frame secured to the baffle;
compressing the cables within the inlets, such that each cable is secured within a separate corresponding inlet to reduce air bypass through the cable management system.

19. The method of claim 18, further comprising the step of securing the baffle to the outer frame by co-axially aligning a plurality of through-holes disposed along the baffle with the apertures of the frame.

20. The method of claim 18, further comprising the step of:
selecting a baffle comprising a desired plurality of inlets from one of:
a baffle comprised of a series of vertically oriented slits which intersect with at least one horizontally oriented slit, the foregoing disposed within the boundary formed by a perimeter wall of the baffle;
a baffle comprised of a series of vertically oriented slits extending from within the boundary formed by the perimeter wall of the baffle and through a surface of the perimeter wall of the baffle; and
a baffle comprised of a series of vertically oriented slits disposed within the boundary formed the perimeter wall of the baffle; and
securing the selected baffle to the frame.
